(19) United States
(12) Patent Application Publication
(10) Pub. No.: US 2022/0243737 A1
(43) Pub. Date: Aug. 4, 2022

(54) VACUUM ASSEMBLY AND VACUUM PUMP WITH AN AXIAL THROUGH PASSAGE

(71) Applicant: Edwards Limited, Burgess Hill, West Sussex (GB)

(72) Inventors: Christopher Mark Bailey, Burgess Hill, Sussex (GB); Declan Scanlan, San Jose, CA (US)

(21) Appl. No.: 17/612,442

(22) PCT Filed: May 15, 2020
(86) PCT No.: PCT/GB2020/051186

§ 371 Date: Nov. 18, 2021

(30) Foreign Application Priority Data
May 24, 2019 (GB) 1907423.6

(51) Int. Cl. F04D 29/053; F04D 19/04; F04D 29/10; F04D 29/52

(52) U.S. Cl. CPC F04D 29/053; F04D 29/524; F04D 29/102; F04D 19/042

(57) ABSTRACT

A vacuum pump and vacuum assembly. The vacuum pump comprises: an inlet for receiving gas; and an exhaust for exhausting the gas; a hollow shaft defining an axial passage extending through the pump from an opening in a base of the pump to an opening axially beyond the pump inlet. The shaft comprises an end remote from the base of the pump, the end being configured to attach to a cathode plate within a vacuum chamber evacuated by the vacuum pump. The shaft is configured for axial movement of the end between at least one open position in which the end is remote from the inlet of the vacuum pump and a sealing position in which the end is closer to the inlet.

### CROSS-REFERENCE OF RELATED APPLICATION

This application is a Section 371 National Stage Application of International Application No. PCT/GB2020/051186, filed May 15, 2020, and published as WO 2020/240155 A1 on Dec. 3, 2020, the content of which is hereby incorporated by reference in its entirety and which claims priority of British Application No. 1907423.6, filed May 24, 2019.

### FIELD

The field of the invention relates to vacuum pumps and a vacuum assembly comprising a base of a vacuum chamber evacuated by such pumps.

### BACKGROUND

Vacuum pumps are used to evacuate chambers such as semiconductor processing chambers for manufacturing semiconductor wafers. In such chambers the symmetry and the uniformity of the gas flow is important; a lack of symmetry leads to non-uniform gas flow and produces corresponding non-uniformities on the wafers.

It is known to provide a vacuum chamber with a turbomolecular pump arranged centrally under the chamber and with a poppet valve to regulate the gas flow and the pressure in the vacuum chamber and to seal the chamber from the pump. Such an arrangement provides a pump, valve and chamber on the same centre line. This gives an improved even gas flow around the wafer and reduces asymmetrical effects caused by other known devices in which the pump and the exhaust port to the pump are located off to one side of the wafer, and in which a pendulum valve which occludes the pump inlet from one side is used. However, although poppet valves have advantages, they do require support and drive means and this can lead to reduced inlet conductance and asymmetries in flow as well as increased hardware costs.

U.S. Pat. No. 6,364,604 discloses a hollow turbomolecular pump with a central axial passage allowing a cathode within the chamber to be supplied with power centrally via the passage leading to increased symmetry in the chamber.

It would be desirable to provide a vacuum pump and chamber with reduced hardware costs and with a substantially uniform gas flow.

The discussion above is merely provided for general background information and is not intended to be used as an aid in determining the scope of the claimed subject matter. The claimed subject matter is not limited to implementations that solve any or all disadvantages noted in the background.

### SUMMARY

A first aspect provides a vacuum pump comprising: an inlet for receiving gas; and

an exhaust for exhausting said gas; a hollow shaft defining at least a portion of an axial passage, said axial passage extending through said pump from an opening in a base of said pump to an opening axially beyond said pump inlet; said shaft comprising an end remote from said base of said pump, said end being configured to attach to a cathode plate within a vacuum chamber evacuated by said vacuum pump, said shaft being configured for axial movement of said end between at least one open position in which said end is remote from said inlet of said vacuum pump and a sealing position in which said end is closer to said inlet.

Embodiments provide a vacuum pump with a shaft that extends through the middle of the vacuum pump which shaft defines at least a portion of an axial passage that extends through the pump. The shaft is configured to attach to a cathode plate within the vacuum chamber that the pump is evacuating. In this way, the axial passage through the pump provides access to the base of the cathode plate allowing power and/or liquids to be supplied to the base of the cathode without requiring the supply means to pass through the chamber and disrupt the flow. Furthermore, by providing an axially movable shaft and configuring the shaft to attach to the cathode plate, movement of the shaft and cathode plate together can cause the cathode plate to move between an open position where the vacuum pump and chamber are in fluid communication with each other and a sealing position where the cathode plate may seal the vacuum chamber from the vacuum pump. In this way, the cathode plate acts as an isolating means for sealing the chamber from the pump and thus, there is no longer a requirement for a poppet valve to provide this sealing.

In this way a pump is provided that allows a symmetric pumping of the vacuum chamber and also allows the vacuum chamber to be sealed without the requirement for an additional sealing plate with the associated drive and support means that this would require.

In some embodiments, the shaft defines the axial passage.

It should be noted that the end of the shaft is configured to attach to the cathode plate. When mounted on the shaft, the cathode plate will be mounted such that it seals against the shaft such that the axial passage is sealed from the vacuum within the chamber. The sealing means may be on the end of the shaft, or on the cathode itself, or on both mating surfaces.

In some embodiments, the vacuum pump comprises an actuating means for axially driving said end of said shaft between said axial positions.

The shaft may be driven to move it axially and this may be done with an electric motor or by pneumatic means. In an alternative embodiment the shaft may be attached to the cathode plate and the cathode plate may be driven by a separate driving means located within the axial passage.

In some embodiments, the vacuum pump comprises control circuitry for controlling said actuating means to position said end of said shaft in a plurality of different open positions in which said end is remote from said inlet of said vacuum pump.

The actuating circuitry is controllable to position the end of the shaft in an open and a sealing position. The cathode plate when attached to the end of the shaft seals the vacuum pump from the vacuum chamber when the shaft is in the sealing position and allows gas flow between the two when the shaft is in the open position. In some embodiments the actuating circuitry may be further operable to position the end of the shaft in a plurality of different open positions. In this regard, a wafer mounted on the cathode plate during semiconductor processing is subject to various processing steps, typically by using an electrically generated plasma in the vacuum chamber. The across-wafer radial uniformity of this process will vary with the axial position of the wafer within the chamber and it may be advantageous to be able to move the wafer to take advantage of these changes during the processing. Embodiments of the present invention use the actuating means that drives the cathode plate between the open and sealing positions to also drive the cathode plate to different axial positions during processing, thereby providing an improved apparatus with reduced hardware.

In some embodiments, said end of said shaft is configured to support said cathode plate.

The end of the shaft may be configured to attach and seal to the underside of the cathode plate and in some embodiments it is configured to support the cathode plate such that movement of the shaft moves the cathode plate. In other cases the shaft may simply provide a sealing surface around the axial passage which can expand or contract with axial movement of the end of the shaft and provide an effective seal between the axial passage and the vacuum within the chamber, the support and driving of the cathode plate being provided by other means within the axial passage.

In some embodiments, a portion of said shaft comprises bellows. In some embodiments, said bellows is configured to expand or contract in response to said actuating means providing said axial movement.

As noted previously, the shaft end moves axially and provides a sealing surface between the vacuum chamber and pump and the axial passage. The shaft including the bellows may define the axial passage through the pump. Thus, as there is axial movement the surface of the shaft will need to expand or contract and bellows are a convenient way of providing such a surface. These bellows may be mounted at any point along the shaft thus, they may be on the upper surface and attached to the cathode plate or they may be located lower down on the shaft or adjacent to the base of the shaft. They may be associated with the actuating means so that the actuating means drives them to expand or contract as required. Bellows are a particularly effective sealing means with no lubricant requirements, or surfaces which slide against a pliant material both of which may lead to contamination of the substrate chamber. Furthermore, seals with relatively moving surfaces may degrade over time due to wear on the relatively moving surfaces, while bellows provide low to zero contamination and are resistant to wear.

In some embodiments, said vacuum pump comprises a rotor and a stator, said rotor and said stator extending around said shaft.

In some embodiments, said vacuum pump comprises a turbomolecular pump.

Generally semiconductor processing chambers such as etching chambers which chambers use cathodes to mount wafers and require symmetrical gas flow are pumped by turbomolecular pumps and turbomolecular pumps according to embodiments, provide the desired symmetrical flow and a suitable vacuum. However, embodiments may comprise different types of pump extending around an axially moveable shaft and these may be suitable for evacuating a chamber where a symmetrical flow is desirable.

In some embodiments, said vacuum pump further comprises said cathode plate mounted on said end of said shaft.

The vacuum pump may be such that the shaft is configured to attach to a cathode plate within a vacuum chamber when evacuating that chamber. Alternatively, the vacuum pump may comprise the cathode plate attached to the shaft, the cathode plate being mounted in the vacuum chamber when the pump is evacuating the chamber.

In some embodiments, said cathode plate comprises annular sealing means around a lower surface of said cathode plate towards an outer circumferential edge, said annular sealing means being configured to seal said vacuum chamber from said vacuum pump when said shaft is in said sealing position.

As noted previously, when the shaft end is in the sealing position the cathode plate seals between the vacuum chamber and the vacuum pump. In order to do this it may in some embodiments have an annular seal on the lower surface which seals either with the pump housing or with the bottom of the vacuum chamber in the sealing position. It should be noted that the sealing means should be able to provide a vacuum seal operable to isolate the vacuum pump which may be at a pressure in the region of mTorr, and the vented vacuum chamber which is at atmospheric pressure.

In some embodiments, a lower surface of said cathode plate facing said axial passage comprises connectors for receiving an electrical supply.

The cathode plate is configured to mount an electrostatic chuck to hold a wafer and requires power and in some cases cooling fluids and control signals to be sent to it. Owing to the design of the pump, the lower surface of the cathode plate facing the axial passage is accessible and thus, in some embodiments comprises connectors for receiving electrical power. In this way electric supply cables can be fed through the axial passage to the lower side of the cathode plate and they do not interfere in the flow within the vacuum chambers and are protected from any substances within the vacuum chamber. The axial passage may also carry cooling/heating supply means which may be in the form of electrical power where thermoelectric devices such as heaters or Peltier devices are embedded in the cathode plate or they may be in the form of cooling/heating fluids. There may also be control signals for controlling the Peltier devices for example sent along cables through the axial passage and there may be measurement signals transmitted to and from control circuitry associated with the vacuum chamber and pump. There may also be a supply of wafer backside helium for wafer cooling transmitted through the axial passage. The shaft should be dimensioned to be able to accommodate the required supplies to the cathode. In this regard the shaft may have a diameter of between 8 and 15 cm preferably about 10 cm, while the pump may have an inlet diameter of a similar size to the cathode plate so between 28 and 32 cm, although in some cases where the cathode plate mates with the vacuum chamber the inlet of the pump may have a larger diameter in the region of 40 to 55 cm.

In some embodiments, said vacuum pump further comprises pressure regulating circuitry configured to regulate a pressure within said vacuum chamber.

As the cathode plate is used to seal between the vacuum chamber and the vacuum pump there is no longer a poppet valve to provide pressure regulation by varying the inlet conductance. In some embodiments, the vacuum pump will have other pressure regulating circuitry associated with it and this may involve control circuitry for adjusting the speed of rotation of the rotor where the pump comprises a rotor and a stator and/or it may comprising circuitry for adjusting the outlet conductance perhaps by adjusting exhaust valve means.

In some embodiments, said vacuum pump comprises a housing, an opening in said housing comprising said pump inlet.

In some embodiments, said housing comprises a sealing means arranged around said pump inlet, said sealing means being configured to mate with a lower surface of said cathode plate when said cathode plate is in said sealing position.

In some cases the lower surface of the cathode plate may mate with an upper surface of the pump housing when the shaft end is in its sealing position and in such a case the upper surface of the pump housing may have a sealing means to seal between the cathode plate and the pump housing when the cathode plate is in contact with it.

In some embodiments, said housing comprises said shaft.

The pump housing may comprise the shaft extending from the base and in this way, there is an integral seal between the base and the shaft as they are formed of one piece.

A second aspect provides a vacuum assembly comprising a vacuum pump according to a first aspect and a vacuum chamber base, said vacuum chamber base comprising an outlet, said vacuum pump being connected to said outlet such that said vacuum pump is operable to evacuate said vacuum chamber through said outlet.

In some embodiments, said vacuum chamber base comprises a support housing for housing and supporting said vacuum pump against said outlet, said shaft extending from a base of said support means, said base comprising an aperture aligned with said axial passage through said shaft.

As an alternative to the base of the pump comprising the shaft the base of the supporting means for the pump may comprise the shaft such that the shaft forms part of the chamber bottom the pump being housed and supported within this portion of the chamber base.

In some embodiments, said vacuum chamber base comprises a sealing means around said outlet, said cathode plate being configured to mate with said sealing means in said sealing position.

In an alternative to the cathode plate sealing with the pump housing it may seal with the chamber bottom and there may be sealing means around the outlet within the upper surface of the chamber bottom.

A third aspect provides a vacuum system comprising a vacuum chamber accommodating a cathode plate for supporting an electrostatic chuck and a vacuum pump according to a first aspect, said vacuum pump being connected to an outlet of said vacuum chamber such that said vacuum pump is operable to evacuate said vacuum chamber through said outlet, said axial passage through said vacuum pump comprising a power source supply means for supplying power to said cathode plate, and at least one of control signal transmission means for transmitting control signals to said cathode plate and thermal energy supply means for transmitting heating or cooling energy to said cathode plate and helium supply means.

The provision of a hollow vacuum pump with a shaft extending through the pump and attached to a cathode plate within a vacuum chamber allows the axial passage through the shaft to be used to send various requirements of the cathode to the cathode plate without requiring the supply means to pass through the chamber. The requirements may include power, with the supply means being electrical wires or cables, they may include temperature control means, which may include power and control signals to control thermo-electrical devices such as Peltier devices embedded in the cathode or pipes for conducting cooling or heating fluids to the cathode. The thermal energy supply means may include a cooling fluid such as liquid helium for cooling the backside of a wafer mounted on the cathode.

Further particular and preferred aspects are set out in the accompanying independent and dependent claims. Features of the dependent claims may be combined with features of the independent claims as appropriate, and in combinations other than those explicitly set out in the claims.

Where an apparatus feature is described as being operable to provide a function, it will be appreciated that this includes an apparatus feature which provides that function or which is adapted or configured to provide that function.

The Summary is provided to introduce a selection of concepts in a simplified form that are further described in the Detailed Description. This summary is not intended to identify key features or essential features of the claimed subject matter, nor is it intended to be used as an aid in determining the scope of the claimed subject matter.

### BRIEF DESCRIPTION OF THE DRAWINGS

Embodiments of the present invention will now be described further, with reference to the accompanying drawings, in which:

FIG. 1 shows a vacuum pump, cathode and base of a vacuum chamber according to one embodiment;

FIG. 2 shows a vacuum pump, cathode and base of a vacuum chamber according to a further embodiment; and

FIG. 3 shows a vacuum pump, cathode and base of a vacuum chamber according to a still further embodiment.

### DETAILED DESCRIPTION

Before discussing the embodiments in any more detail, first an overview will be provided.

In a typical conventional plasma etch chamber, a valve (gate, pendulum, or poppet) is installed between the turbo pump and the main chamber, and serves two functions:

1. Automatic Pressure Control (APC): where the movement of the plate of the valve is controlled to operate between a fully open and fully closed position to proportionally throttle gas flow, and therefore allow pressure control with the chamber; and
2. Isolation: where in the fully closed and sealed position, the turbo pump is vacuum sealed from the chamber, and so can remain under vacuum while the chamber is at atmosphere.

Embodiments provide an arrangement where there is no valve of this type between the pump and the chamber. In such embodiments, pressure control is either not provided or is provided by a different means, (for example by controlling the rotational speed of the turbo pump, or throttling the exhaust of the turbo pump, or with the use of controllable flow restrictors such as baffles further upstream in the chamber.

The second function of isolation is provided by using a system with a movable cathode plate such that the cathode plate is lowered onto the pump (or chamber housing holding the pump) and forming a vacuum seal. This allows normal maintenance of the chamber to be carried out while the pump remains under vacuum,

In embodiments a vacuum seal is provided between the top surface of the pump and the bottom surface of the chamber cathode plate such that when sealed the pump can remain under vacuum while the chamber can be vented to atmosphere.

In another configuration, the chamber housing that holds the hollow pump may be used to seal with the cathode, to again provide the same isolation between the turbo pump at vacuum and the chamber at atmosphere.

In summary the conventional APC or poppet valve between the chamber and the pump which typically provided isolation between the pump and chamber is dispensed with.

The isolation function is provided by forming a vacuum seal between the bottom of a movable cathode and the top of the pump or the top of the chamber housing the pump

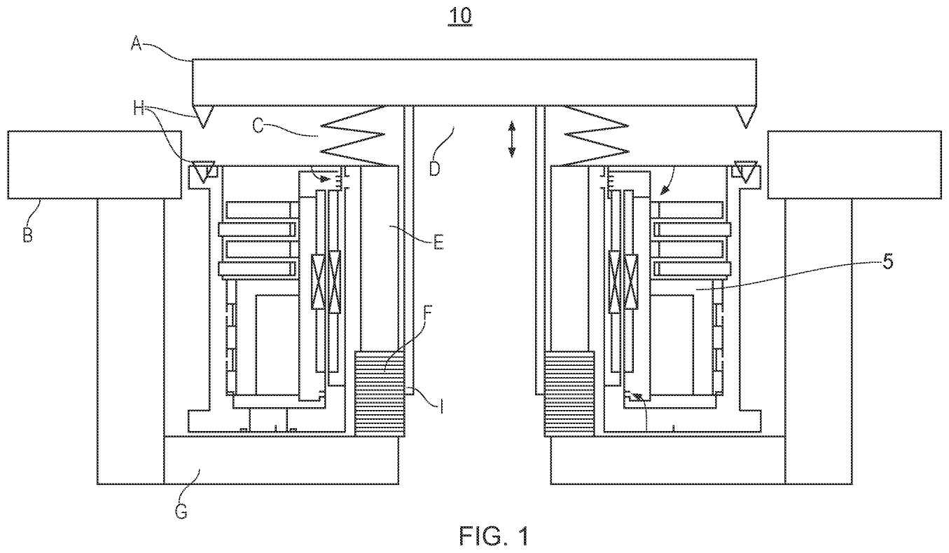

FIG. 1 shows a design of a turbo pump with a hole in the middle according to an embodiment. The pump comprises a vacuum seal (H) formed between the top surface of the pump and the bottom surface of the chamber cathode (A) such that when sealed the pump can remain under vacuum while the chamber can be vented to atmosphere.

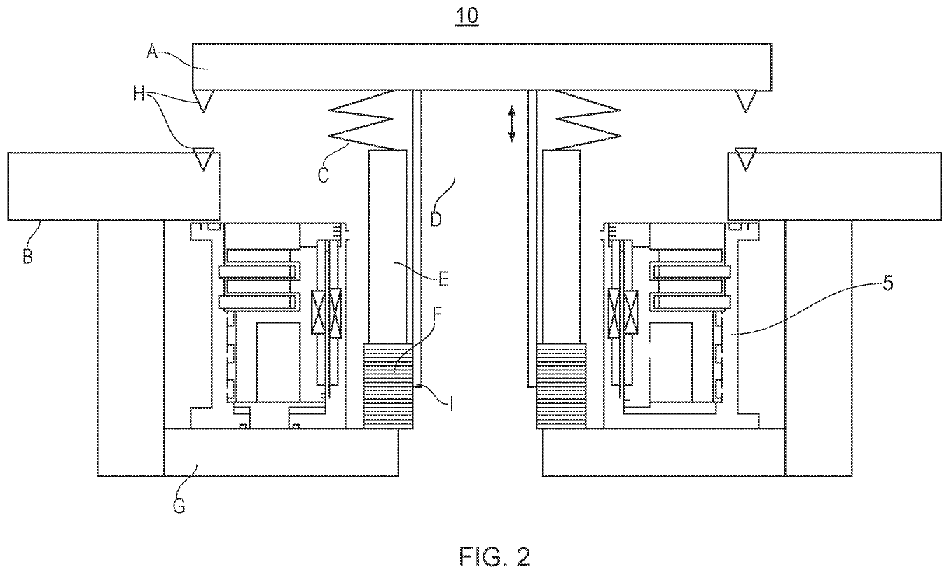

In another configuration FIG. 2, the chamber housing that holds the hollow turbo pump is used to seal with the cathode, to again provide the same isolation between the turbo pump at vacuum and the chamber at atmosphere.

Each embodiment relies on the concept of a movable cathode. In the drawings, this design is shown with a bellows (C) attached between the bottom of the cathode (A) and cathode support rod (or tube) (E), which is moved up and down by a cathode actuator (F). The normal process position is up, while to isolate the turbo pump the position is down.

Other potential variations of this design would include no bellows, but with the support rod attached directly to the cathode, while the cathode actuator would include a mechanism to extend up and down the support rod.

The seal (H) is configured to seal the TMP area (at mTorr pressures) from the surrounding chamber area (up to atmospheric pressures)

In FIG. 1 vacuum pump 5 which in this embodiment is a hollow turbo pump with a drag stage is mounted within a support housing which forms part of the base of vacuum chamber 10.

Within vacuum chamber 10 there is a cathode (A) which is sealingly attached to shaft (E). Shaft (E) and the cathode mounted thereon are configured to move axially, that is parallel to an axis running through the pump, between one or more open positions where vacuum chamber 10 is in fluid communication with vacuum pump 5 and a closed or sealed position where cathode (A) seals with the upper surface of the pump housing and isolates vacuum chamber 10 from pump 5.

There are sealing surfaces (H) on the underside of cathode (A) and on the upper side of the pump housing which sealing surfaces mate to form an effective seal and isolate the vacuum pump from the vacuum chamber which can then be vented. In this way, the vacuum pump is protected from pressure rises within the vacuum chamber. A vacuum chamber in a semiconductor manufacturing plant for example may require frequent servicing during which the pressure in the chamber will rise. It is important that this pressure rise is not transmitted to the areas downstream of the vacuum chamber where a vacuum should be maintained.

By using a movable cathode as a sealing plate to isolate the pump from the chamber, the conventional sealing plate such as that associated with a poppet valve can be dispensed with, reducing hardware and impediments in the flow path thereby improving conductance. Furthermore, as the cathode is mounted on shaft (E) extending through the centre of pump 5 the cathode is symmetrically mounted and asymmetries in gas flow are avoided or at least reduced.

The use of a hollow vacuum pump allows access to the underside of cathode (A) via an axial passage (D) through the centre of the pump. It is important that this axial passage and the interior of the vacuum chamber are isolated from each other to avoid or at least impede leakage of the higher pressure external to the vacuum chamber into the vacuum chamber. Thus, the shaft (E) that defines the axial passage has an impervious annular wall along its length and is sealed against the underside of cathode (A) and is integral or sealed with the base of the vacuum pump 5 or the base of the chamber 10.

In this embodiments the base of the chamber (B) comprises a portion extending from the base, this portion housing and supporting vacuum pump 5 and having a base (G) which extends up to form shaft (E) whose upper surface in this embodiment is in the form of bellows (C) and mates with the under surface of cathode (A). In this embodiment, there is an actuator (F) which drives a cylinder (I) that is attached to the underside of cathode (A) and drives the cathode (A) up or down depending on the movement of actuator F. Bellows (C) expands or contracts with the movement of the cathode, thereby maintaining the seal between the chamber and axial passage while the cathode (A) moves between an open position where the vacuum chamber 10 is in fluid communication with vacuum pump 5 and a closed sealed position where the vacuum chamber 10 is isolated from vacuum pump 5. Bellows provide a convenient manner of allowing axial movement while providing a seal. It would be clear to a skilled person though that any means that allows or provides axial movement and can still provide a seal would be appropriate. In this embodiment, the bellows forms the top portion of the shaft, in other embodiments, it may be located towards the base of the shaft or somewhere in the middle of the shaft.

In some embodiments, the cathode (A) may be axially movable into several different positions in which the pump and chamber are in fluid communication. The position of the wafer within the chamber affects the electric field experienced by the wafer and it may be advantageous to be able to adjust the position of the wafer during different parts of the manufacturing process. Providing a moveable cathode that allows the cathode to move to seal the chamber also allows control of the cathode and thus, the wafer position within the chamber and in this way hardware used to seal the chamber can also be used for positioning the wafer as desired.

As can be seen, the cathode acts as a seal to the chamber but it is not used to control inlet conductance. Thus, in some embodiments a separate pressure regulator (not shown) may be associated with the vacuum pump 5 which regulator is configured to control at least one of the rotational speed and the outlet conductance of the pump.

FIG. 2 shows an alternative embodiment, where cathode (A) seals directly with the base of the chamber body (B). In this case the turbo pump 5 is mounted within the support housing in a similar manner to the first embodiment but it is the base of the vacuum chamber (B) that seals with the cathode.

It should be noted that the seals between the under surface of cathode (A) and the upper surface of the chamber base (B) may have a number of forms, they may for example comprise labyrinthine paths with sealing elastomeric material within them which paths mate as the cathode moves to the sealing position and thereby provide effective sealing means.

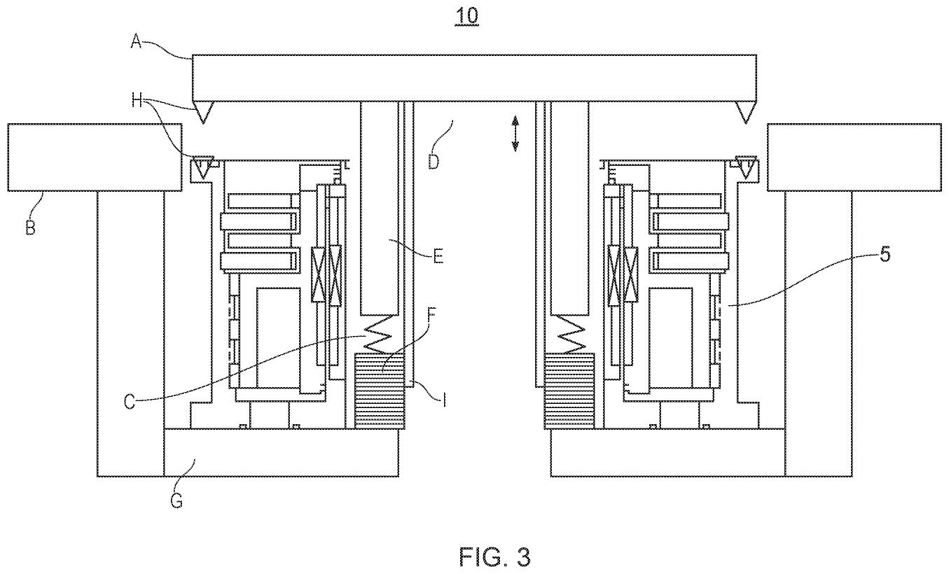

FIG. 3 shows a third embodiment, where the means for driving the cathode is again a cylinder (I) within shaft (E), which cylinder is driven axially by actuating means (F) and provides the force for moving cathode (A) between different axial positions. In this embodiment the bellows (C) portion of the shaft is towards the base of the shaft and adjacent to the actuating means that drives the cylinder (I). In some embodiments, the cylinder (I) may not contact the cathode but may contact a protrusion in the shaft extending in to the axial passage and located above the bellows, such that the cylinder drives the portion of the shaft (E) above bellows (C) up and down.

Although illustrative embodiments of the invention have been disclosed in detail herein, with reference to the accompanying drawings, it is understood that the invention is not limited to the precise embodiment and that various changes and modifications can be effected therein by one skilled in the art without departing from the scope of the invention as defined by the appended claims and their equivalents.

Although elements have been shown or described as separate embodiments above, portions of each embodiment may be combined with all or part of other embodiments described above.

Although the subject matter has been described in language specific to structural features and/or methodological acts, it is to be understood that the subject matter defined in the appended claims is not necessarily limited to the specific features or acts described above. Rather, the specific features and acts described above are described as example forms of implementing the claims.

1. A vacuum pump comprising:
an inlet for receiving gas; and
an exhaust for exhausting said gas;
a hollow shaft defining at least a portion of an axial passage, said axial passage extending through said pump from an opening in a base of said pump to an opening axially beyond said pump inlet;
said shaft comprising an end remote from said base of said pump, said end being configured to attach to a cathode plate within a vacuum chamber evacuated by said vacuum pump, said shaft being configured for axial movement of said end between at least one open position in which said end is remote from said inlet of said vacuum pump and a sealing position in which said end is closer to said inlet.

2. The vacuum pump according to claim 1, said vacuum pump comprising an actuating means for axially driving said end of said shaft between said axial positions.

3. The vacuum pump according to claim 2, comprising control circuitry for controlling said actuating means to position said end of said shaft in a plurality of different open positions in which said end is remote from said inlet of said vacuum pump.

4. The vacuum pump according to claim 1, wherein said end of said shaft is configured to support said cathode plate.

5. The vacuum pump according to claim 1, wherein a portion of said shaft comprises bellows, said bellows being configured to expand or contract in response to said axial movement.

6. The vacuum pump according to claim 1, said vacuum pump comprising a rotor and a stator, said rotor and said stator extending around said shaft.

7. The vacuum pump according to claim 6, said vacuum pump comprising a turbomolecular pump.

8. The vacuum pump according to claim 1, said vacuum pump further comprising said cathode plate mounted on said end of said shaft.

9. The vacuum pump according to claim 8, said cathode plate comprising annular sealing means around a lower surface of said cathode plate towards an outer circumferential edge, said annular sealing means being configured to seal said vacuum chamber from said vacuum pump when said shaft is in said sealing position.

10. The vacuum pump according to claim 8, wherein a lower surface of said cathode plate facing said axial passage comprises connectors for receiving electrical supply cables.

11. The vacuum pump according to claim 1, said vacuum pump further comprising pressure regulating circuitry configured to regulate a pressure within said vacuum chamber.

12. The vacuum pump according to claim 1, said vacuum pump comprising a housing, an opening in said housing comprising said pump inlet.

13. The vacuum pump according to claim 12, said housing comprising a sealing means arranged around said pump inlet, said sealing means being configured to mate with said cathode plate when said cathode plate is in said sealing position.

14. The vacuum pump according to claim 12 said housing comprising at least a portion of said shaft.

15. The vacuum assembly, comprising a vacuum pump according to claim 1, and a vacuum chamber base, said vacuum chamber base comprising an outlet, said vacuum pump being connected to said outlet such that said vacuum pump is operable to evacuate said vacuum chamber through said outlet.

16. A vacuum assembly according to claim 15, said vacuum chamber base comprising a support housing for housing and supporting said vacuum pump against said outlet, said shaft extending from a base of said support means, said base comprising an aperture aligned with said axial passage through said shaft.

17. A vacuum assembly according to claim 15, said vacuum chamber base comprising a sealing means around said outlet, said cathode plate being configured to mate with said sealing means in said sealing position.

18. A vacuum system comprising a vacuum chamber accommodating a cathode for supporting an electrostatic chuck and a vacuum pump according to claim 1, said vacuum pump being connected to an outlet of said vacuum chamber such that said vacuum pump is operable to evacuate said vacuum chamber through said outlet, said axial passage through said vacuum pump comprising a power source supply means for supplying power to said cathode, and at least one of control signal transmission means for transmitting control signals to said cathode and thermal energy supply means for transmitting heating or cooling energy to said cathode.
